(19) United States
(12) Patent Application Publication
(10) Pub. No.: US 2023/0246025 A1
(43) Pub. Date: Aug. 3, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventor: Taro MORIYA, Tokyo (JP)

(21) Appl. No.: 18/059,129

(22) Filed: Nov. 28, 2022

(30) Foreign Application Priority Data
Feb. 1, 2022 (JP) 2022-014036

(51) Int. Cl. H01L 27/088; H01L 29/06; H01L 29/10; H01L 29/78; H01L 21/306; H01L 21/308; H01L 29/66; H01L 21/8234

(52) U.S. Cl. CPC H01L 27/088; H01L 29/0634; H01L 29/1095; H01L 29/7813; H01L 21/30604; H01L 21/308; H01L 29/66734; H01L 21/823475

(57) ABSTRACT

A semiconductor substrate has a first main surface and a second main surface opposite to each other, and includes a substrate body and an epitaxial layer. A first power MOSFET is formed in a first region defined in the semiconductor substrate, and a second power MOSFET is formed in a second region defined in the semiconductor substrate. A thickness of the epitaxial layer in the first region located between a first main surface's first portion and a second main surface's first portion is less than a thickness of the epitaxial layer in the second region located between a first main surface's second portion and a second main surface's second portion.

### CROSS-REFERENCE TO RELATED APPLICATIONS

The disclosure of Japanese Patent Application No. 2022-014036 filed on Feb. 1, 2022 including the specification, drawings and abstract is incorporated herein by reference in its entirety.

### BACKGROUND

The present invention relates to a semiconductor device and a method of manufacturing the semiconductor device, and is, for example, suitable for an in-vehicle semiconductor device comprising a power MOSFET (Metal Oxide Semiconductor Field Effect Transistor) as a switching element.

In recent years, switches in which power MOSFETs are applied as semiconductor elements have been used in in-vehicle semiconductor devices. One example of such a switch is capable of supplying or cutting off power from a battery to components that require power, such as headlights, power windows, or the like.

A cable connected to the battery may be removed when maintenance such as battery inspection or replacement is performed, and may be reconnected after maintenance is completed. At this time, it is assumed that the cable is connected with reverse polarity from its original polarity (connected in reverse).

In a case where the cable is connected in reverse to the battery, current would flow in a switch using a power MOSFET via a parasitic diode of the power MOSFET even if the switch is turned off. That is, current would flow backward in a state where the switch is turned off.

There are disclosed techniques listed below.
[Patent Document 1] Japanese Unexamined Patent Application Publication No. 2002-368219
[Patent Document 2] Japanese Unexamined Patent Application Publication No. 2016-207716

Patent Document 1 discloses a semiconductor device in which two power MOSFETs having respective drains connected to each other and one semiconductor chip are connected in series (connected in anti-series) in order to prevent such a backward flow of the current. Further, Patent Document 2 discloses a semiconductor device having a column structure in order to reduce an ON-resistance when current flows in two power MOSFETs connected in series (connected in anti-series).

### SUMMARY

In the semiconductor device in which a power MOSFET is applied as a switch, there is a need to further reduce the ON-resistance when current flows in the power MOSFET.

Other issues and novel features will become apparent from the description in the present specification and accompanying drawings.

A semiconductor device according to an embodiment of the present invention comprises a semiconductor substrate, a first region and a second region, a first switching element, and a semiconductor element. The semiconductor substrate has a first main surface and a second main surface opposite to each other. The first region and the second region are each defined in the semiconductor substrate. The first switching element is formed in the first region, and is configured to perform current conduction between the first main surface and the second main surface. The semiconductor element is formed in the second region. The semiconductor substrate includes a substrate body of a first conductivity type and a semiconductor layer of the first conductivity type. The semiconductor layer is formed so as to be in contact with the substrate body, and has the first main surface. In the semiconductor layer, a thickness of a portion located in the first region and where current conduction by the first switching element is performed is a first thickness. In the semiconductor layer, a thickness of a portion located in the second region and where current conduction by the semiconductor element is performed is a second thickness. The first thickness is less than the second thickness.

A method of manufacturing a semiconductor device according to another embodiment includes the following steps. A semiconductor substrate is prepared. The semiconductor substrate has a first main surface and a second main surface opposite to each other, and includes a first region and a second region each defined in the semiconductor substrate, a substrate body of a first conductivity type, and a semiconductor layer of the first conductivity type. The substrate body has the second main surface, the semiconductor layer is formed so as to be in contact with the substrate body, and the semiconductor layer has the first main surface. A first switching element configured to perform current conduction between the first main surface and the second main surface is formed in the first region of the semiconductor substrate, and a semiconductor element is formed in the second region of the semiconductor substrate. A first thickness located in the first region is made to be less than a second thickness located in the second region. The first thickness is the thickness of a portion in the semiconductor layer where current conduction by the first switching element is performed. The second thickness is the thickness of a portion in the semiconductor layer where current conduction by the semiconductor element is performed.

According to the semiconductor device of the embodiment, it is possible to further reduce the ON-resistance.

According to the method of manufacturing a semiconductor device of another embodiment, it is possible to manufacture a semiconductor device capable of further reducing the ON-resistance.

### BRIEF DESCRIPTION OF THE DRAWINGS

FIG. 1 is a circuit diagram of an example of a circuit including semiconductor devices according to first to third embodiments.

FIG. 2 is a plan view of an example of a planar pattern of the semiconductor device according to the first embodiment.

FIG. 3 is a cross-sectional view of the semiconductor device according to the same embodiment taken along a line III-III of FIG. 2.

FIG. 4 is a cross-sectional view of the semiconductor device according to the same embodiment in an example of a manufacturing step thereof.

FIG. 5 is a cross-sectional view of the semiconductor device according to the same embodiment in a manufacturing step continued from FIG. 4.

FIG. 6 is a cross-sectional view of the semiconductor device according to the same embodiment in another example of a manufacturing step shown in FIG. 4.

FIG. 7 is a cross-sectional view of the semiconductor device according to the same embodiment in a manufacturing step continued from FIG. 5 or FIG. 6.

FIG. 8 is a cross-sectional view of the semiconductor device according to the same embodiment in a manufacturing step continued from FIG. 7.

FIG. 9 is a cross-sectional view of the semiconductor device according to the same embodiment in a manufacturing step continued from FIG. 8.

FIG. 10 is a cross-sectional view of the semiconductor device according to the same embodiment in a manufacturing step continued from FIG. 9.

FIG. 11 is a cross-sectional view of the semiconductor device according to the same embodiment in a manufacturing step continued from FIG. 10.

FIG. 12 is a cross-sectional view of the semiconductor device according to the same embodiment in a manufacturing step continued from FIG. 11.

FIG. 13 is a cross-sectional view of the semiconductor device according to the same embodiment in a manufacturing step continued from FIG. 12.

FIG. 14 is a cross-sectional view of the semiconductor device according to the same embodiment in a manufacturing step continued from FIG. 13.

FIG. 15 is a cross-sectional view for describing an operation of the semiconductor device according to the same embodiment in a case where a battery is properly connected.

FIG. 16 is a circuit diagram for describing the operation of the semiconductor device according to the same embodiment in a case where the battery is properly connected.

FIG. 17 is a cross-sectional view for describing the operation of the semiconductor device according to the same embodiment in a case where the battery is connected in reverse.

FIG. 18 is a circuit diagram for describing the operation of the semiconductor device according to the same embodiment in a case where the battery is connected in reverse.

FIG. 19 is a cross-sectional view of the semiconductor device according to a second embodiment.

FIG. 20 is a cross-sectional view of the semiconductor device according to the same embodiment in a manufacturing step thereof.

FIG. 21 is a cross-sectional view of the semiconductor device according to the same embodiment in a manufacturing step continued from FIG. 20.

FIG. 22 is a cross-sectional view of the semiconductor device according to the same embodiment in a manufacturing step continued from FIG. 21.

FIG. 23 is a cross-sectional view for describing the operation of the semiconductor device according to the same embodiment in a case where the battery is properly connected and in a case where the battery is connected in reverse.

FIG. 24 is a cross-sectional view of the semiconductor device according to a third embodiment.

FIG. 25 is a cross-sectional view of the semiconductor device according to the same embodiment in a manufacturing step thereof.

FIG. 26 is a cross-sectional view of the semiconductor device according to the same embodiment in a manufacturing step continued from FIG. 25.

FIG. 27 is a cross-sectional view for describing the operation of the semiconductor device according to the same embodiment in a case where the battery is properly connected and in a case where the battery is connected in reverse.

FIG. 28 is a cross-sectional view of the semiconductor device according to a fourth embodiment.

FIG. 29 is a cross-sectional view of the semiconductor device according to the same embodiment in a manufacturing step thereof.

FIG. 30 is a cross-sectional view of the semiconductor device according to the same embodiment in a manufacturing step continued from FIG. 29.

FIG. 31 is a cross-sectional view for describing the operation of the semiconductor device according to the same embodiment.

FIG. 32 is a cross-sectional view of the semiconductor device according to a fifth embodiment.

FIG. 33 is a cross-sectional view of the semiconductor device according to the same embodiment in a manufacturing step thereof.

FIG. 34 is a cross-sectional view of the semiconductor device according to the same embodiment in a manufacturing step continued from FIG. 33.

FIG. 35 is a cross-sectional view for describing the operation of the semiconductor device according to the same embodiment.

### DETAILED DESCRIPTION

First, a circuit applied to a semiconductor device in which two power MOSFETs serving as a switch connected in reverse and connected in series (connected in anti-series) to each other will be described. Note that “connected in anti-series” in the present specification means, for example, a connection relationship on the circuit shown in FIG. 1, that is, an electrical connection relationship.

As shown in FIG. 1, a first power MOSFET TMT1 and a second power MOSFET TMT2 are electrically connected in series (connected in anti-series) via a common drain region CDN. A cathode of a battery BA is electrically connected to a source S1 of the first power MOSFET TMT1, and an anode of the battery BA is electrically connected to a source S2 of the second power MOSFET TMT2 (proper connection). A load LAD of, for example, headlights or the like is electrically connected between the source S2 and the battery BA. Hereinafter, a structure of the semiconductor device will be described in detail.

### First Embodiment

Here, a first example of a semiconductor device SDV in which two power MOSFETs are connected in reverse and connected in series (connected in anti-series) to each other will be described.

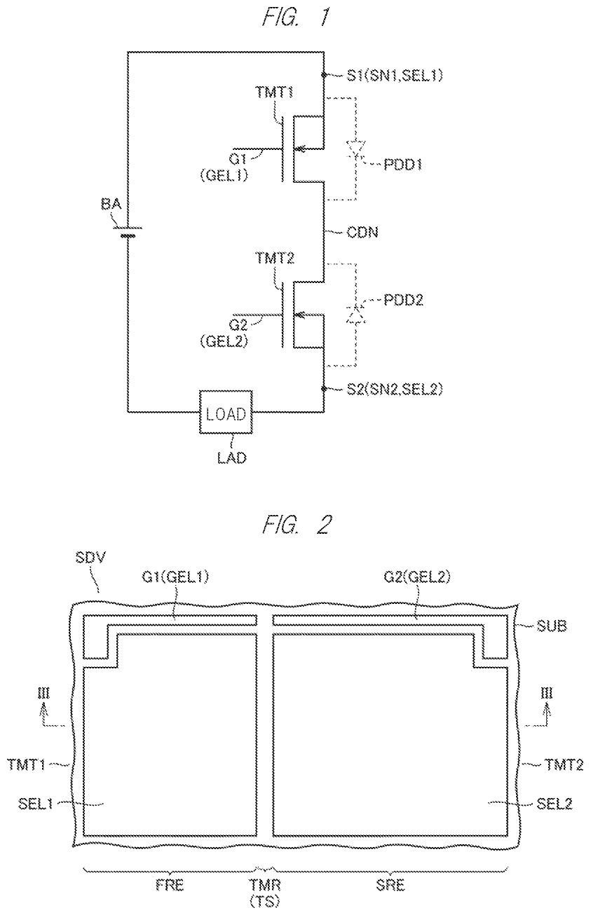

As shown in FIGS. 2 and 3, the first power MOSFET TMT1 (first switching element) and the second power MOSFET TMT2 (second switching element) are formed on the same semiconductor substrate SUB. The first power MOSFET TMT1 has a columnless structure with no columns. The second power MOSFET TMT2 has a super-junction structure (SJ structure) with columns CLM.

The semiconductor substrate SUB has a first main surface FMS and a second main surface SMS opposite to each other. The semiconductor substrate SUB includes an N-type substrate body SBY having the second main surface SMS, and an N⁻-type epitaxial layer NEL (semiconductor layer) having the first main surface FMS. The N⁻-type epitaxial layer NEL is formed so as to be in contact with the substrate body SBY. The substrate body SBY is set to have an N-type impurity concentration that is higher by, for example, about two orders of magnitude than the epitaxial layer NEL.

A first region FRE and a second region SRE are each defined in the semiconductor substrate SUB. The first power MOSFET TMT1 is formed in the first region FRE. The second power MOSFET TMT2 is formed in the second region SRE. The first main surface FMS of the semiconductor substrate SUB includes a first main surface's first portion FMS1 located in the first region FRE, and a first main surface's second portion FMS2 located in the second region SRE.

The second main surface SMS includes a second main surface's first portion SMS1 located in the first region FRE, and a second main surface's second portion SMS2 located in the second region SRE. The second main surface's first portion SMS1 and the second main surface's second portion SMS2 are located on the same plane. In a cross-sectional view, the first main surface's first portion FMS1 is located closer to the second main surface SMS than the first main surface's second portion FMS2.

Here, a thickness of a portion of the epitaxial layer NEL that is located in the first region FRE and between the first main surface's first portion FMS1 and the second main surface's first portion SMS1, and becomes a channel region where current conduction is performed is defined as a thickness TK1. In addition, a thickness of a portion of the epitaxial layer NEL that is located in the second region SRE and between the first main surface's second portion FMS2 and the second main surface's second portion SMS2, and becomes a channel region where current conduction is performed is defined as a thickness TK2. The thickness TK1 is less than the thickness TK2.

Next, structures of the first power MOSFET TMT1 and the second power MOSFET TMT2 will be described in more detail.

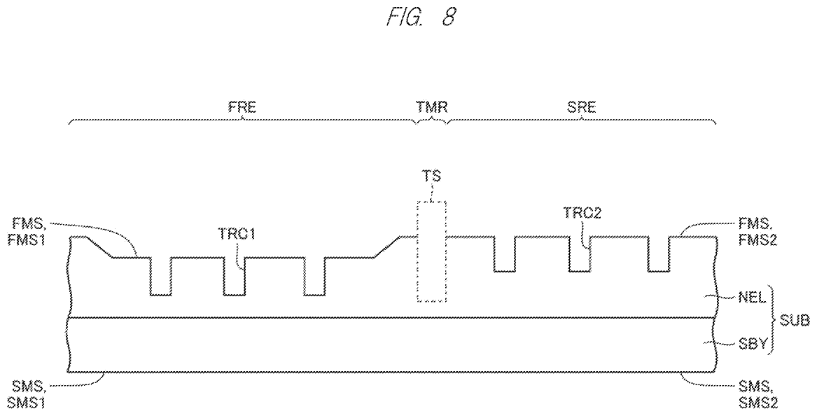

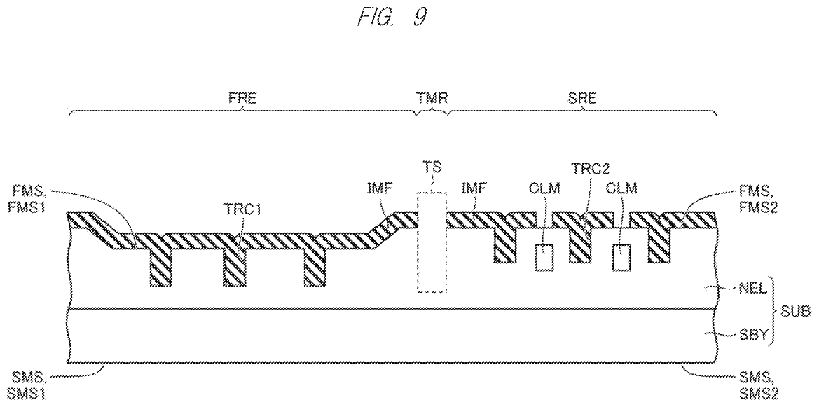

The first region FRE in which the first power MOSFET TMT1 is formed has a trench TRC1 (see FIG. 8) in which a gate electrode GEL1 (first electrode) is formed with a gate oxide film GZ1 (first insulating film) interposed therebetween. A P⁻ region PM1 (first impurity region's first portion) is formed so as to extend from a surface of the first main surface's first portion FMS1 (epitaxial layer NEL) of the semiconductor substrate SUB to a position shallower than a bottom of the gate electrode GEL1 so as to be in contact with the gate oxide film GZ1. An N⁺ region SN1 (second impurity region's first portion) is formed so as to extend from the surface of the first main surface's first portion FMS1 (epitaxial layer NEL) of the semiconductor substrate SUB to a position shallower than a bottom of the P⁻ region PM1. The N⁺ region SN1 serves as a source region of the first power MOSFET TMT1.

The second region SRE in which the second power MOSFET TMT2 is formed has a trench TRC2 (see FIG. 8) in which a gate electrode GEL2 (second electrode) is formed with a gate oxide film GZ2 (second insulating film) interposed therebetween. A P⁻ region PM2 (first impurity region's second portion) is formed so as to extend from a surface of the first main surface's second portion FMS2 (epitaxial layer NEL) of the semiconductor substrate SUB to a position shallower than a bottom of the gate electrode GEL2 so as to be in contact with the gate oxide film GZ2.

P-type columns CLM (first columnar bodies) are formed so as to extend from a bottom of the P⁻ region PM2 toward the substrate body SBY. The columns CLM are arranged so as to be spaced apart from one another along a direction in which the gate electrode GEL2 extends (direction orthogonal to a plane of the drawing). An N⁺ region SN2 (second impurity region's second portion) is formed so as to extend from the surface of the first main surface's second portion FMS2 (epitaxial layer NEL) of the semiconductor substrate SUB to a position shallower than the bottom of the P⁻ region PM2. The N⁺ region SN2 serves as a source region of the second power MOSFET TMT2.

An interlayer insulating film ILF is formed so as to cover the first main surface FMS of the semiconductor substrate SUB. Plugs PLG1 are formed in the first region FRE so as to penetrate the interlayer insulating film ILF. Plugs PLG2 are formed in the second region SRE so as to penetrate the interlayer insulating film ILF. A source electrode SEL1 is formed in the first region FRE so as to cover the interlayer insulating film ILF. A source electrode SEL2 is formed in the second region SRE so as to cover the interlayer insulating film ILF.

The source electrode SEL1 and the N⁺ region SN1 are electrically connected in the first region FRE via the plugs PLG1. The source electrode SEL2 and the N⁺ region SN2 are electrically connected in the second region SRE via the plugs PLG2. The plugs PLG1 (PLG2) may be formed in stripes or formed so as to be spaced apart from one another along a direction in which the gate electrode GEL1 (GEL2) extends (direction orthogonal to the plane of the drawing).

As shown in FIG. 2, a gate G1 electrically connected to the gate electrode GEL1 of the first power MOSFET TMT1 is arranged on a side of the source electrode SEL1 in the first region FRE. A gate G2 electrically connected to the gate electrode GEL2 of the second power MOSFET TMT2 is arranged on a side of the source electrode SEL2 in the second region SRE.

An outer peripheral region TMR is defined in the semiconductor substrate SUB so as to surround each of the first region FRE and the second region SRE. Note that FIG. 2 shows the outer peripheral region TMR located between the first region FRE and the second region SRE. An outer peripheral structure TS configured to block current leakage is formed in the outer peripheral region TMR.

The semiconductor substrate SUB is mounted on a lead frame LEF. The lead frame LEF is arranged so as to be in contact with the second main surface SMS of the substrate body SBY (semiconductor substrate SUB). The substrate body SBY and the lead frame LEF serve as the common drain region CDN (drain electrode) of the first power MOSFET TMT1 and the second power MOSFET TMT2. Note that, for example, a metal back surface BME may be formed instead of the lead frame LEF.

As described below, in a case where the battery BA is properly connected, breakdown voltage is ensured by the second power MOSFET TMT2. On the other hand, in a case where the battery BA is connected with reverse polarity, the breakdown voltage is ensured by the first power MOSFET TMT1.

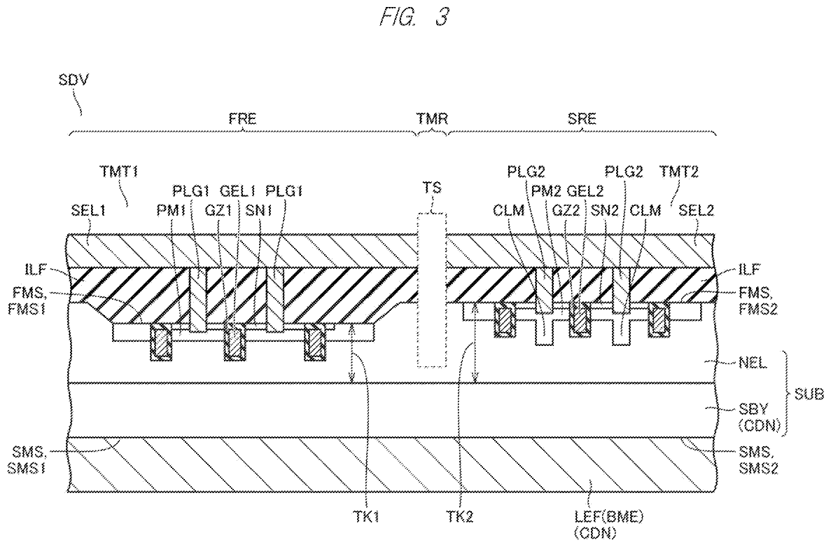

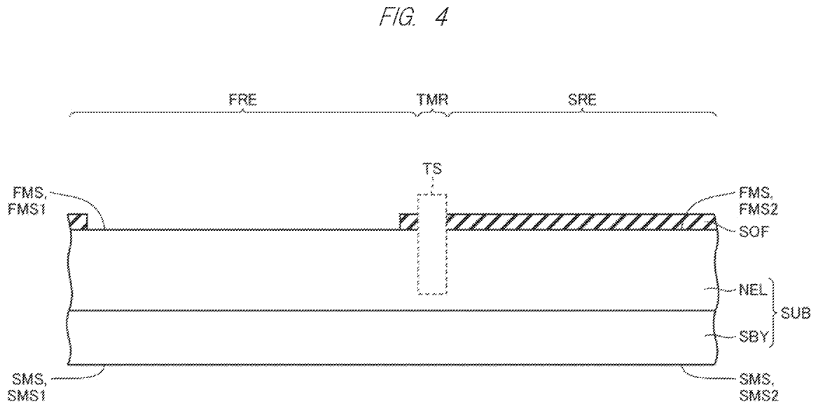

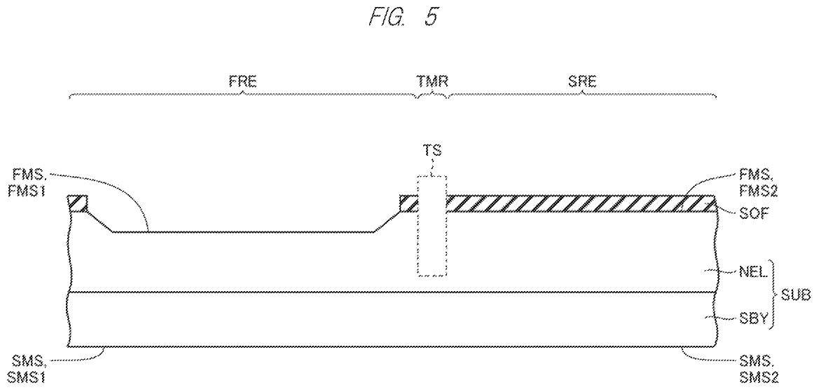

Next, an example of a method of manufacturing the above-described semiconductor device SDV will be described. As shown in FIG. 4, the semiconductor substrate SUB having the N⁻-type epitaxial layer NEL grown on one surface of the substrate body SBY by an epitaxial growth method is prepared. Next, a silicon oxide film SOF is formed by, for example, a CVD (Chemical Vapor Deposition) method so as to cover the first main surface FMS of the semiconductor substrate SUB (epitaxial layer NEL).

Next, a portion of the silicon oxide film SOF located in the first region FRE is removed by a photolithography process and an etching process while a portion of the silicon oxide film SOF located in the second region SRE is left as is, thereby exposing a surface of the epitaxial layer NEL.

Next, as shown in FIG. 5, the exposed epitaxial layer NEL is subjected to, for example, a TMAH (TetraMethylAmmonium Hydroxide) etching process using the silicon oxide film SOF as an etching mask. This allows etching to progress along a (111) plane orientation of the epitaxial layer NEL (silicon) such that a position of the first main surface's first portion FMS1 is set back toward the substrate body SBY with respect to a position of the first main surface's second portion FMS2. The thickness TK1 of the epitaxial layer NEL in the first region FRE (see FIG. 3) is adjusted by an etching amount. Thereafter, the silicon oxide film SOF is removed, thereby exposing the entire surface of the epitaxial layer NEL as shown in FIG. 7.

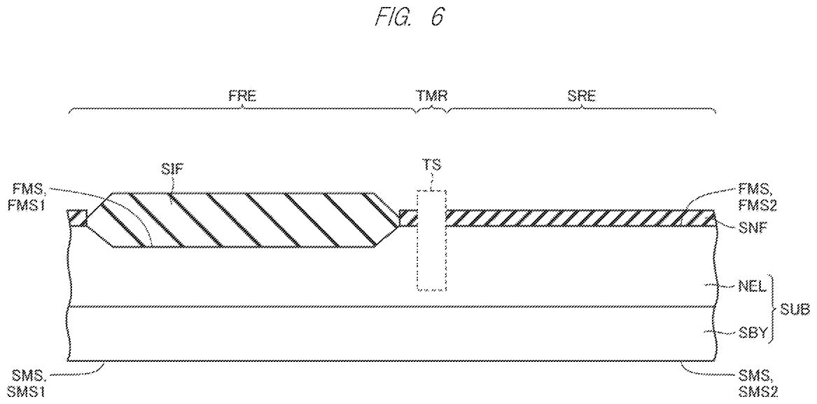

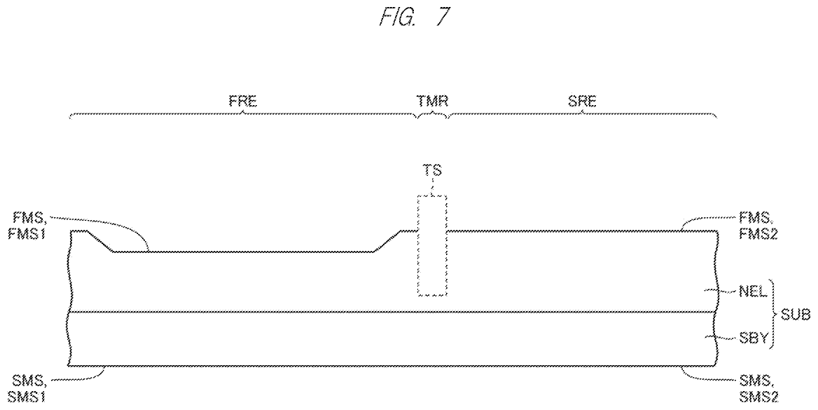

Note that, in the TMAH etching process, there is almost no damage to the surface of the epitaxial layer NEL as compared to, for example, a dry etching process, and an operation of the power MOSFET formed thereafter is prevented from being affected. In addition to the TMAH etching process, a method of forming a thick oxide film and then removing the oxide film may be applied in this step. As shown in FIG. 6, a silicon nitride film SNF is formed so as to cover the first main surface FMS of the semiconductor substrate SUB, and a portion of the silicon nitride film SNF located in the first region FRE is removed by the photolithography process and the etching process, thereby exposing the surface of the epitaxial layer NEL.

Next, a relatively thick silicon oxide film SIF is formed by oxidizing the exposed surface of the epitaxial layer NEL by a thermal oxidation process. Next, a position of the first main surface's first portion FMS1 is set back toward the substrate body SBY with respect to a position of the first main surface's second portion FMS2 by removing the silicon oxide film SIF. The thickness TK1 of the epitaxial layer NEL in the first region FRE (see FIG. 3) is adjusted by a film thickness of the silicon oxide film SIF. Thereafter, the silicon nitride film SNF is removed, thereby exposing the entire surface of the epitaxial layer NEL as shown in FIG. 7.

Next, the trenches TRC1 and TRC2 are formed in the epitaxial layer NEL by the photolithography process and the etching process (see FIG. 8). This allows the trench TRC1 to be formed in the first region FRE as shown in FIG. 8. The trench TRC2 is formed in the second region SRE.

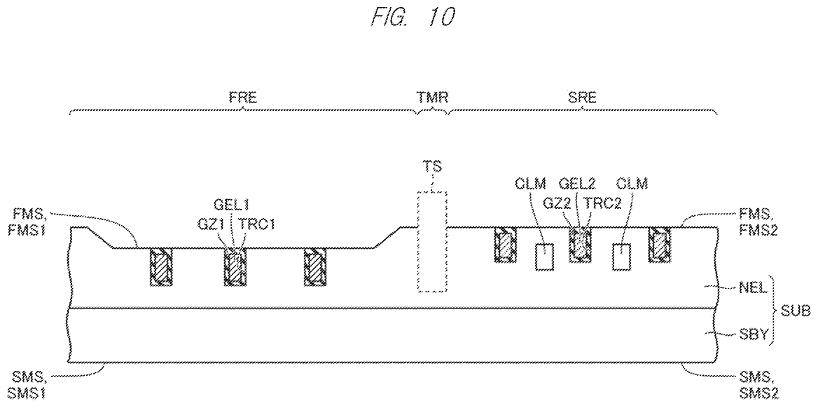

Next, an injection mask for forming columns is formed. A silicon oxide film IMF is formed by, for example, the CVD method so as to cover the first main surface FMS of the semiconductor substrate SUB (epitaxial layer NEL) (see FIG. 9). Next, as shown in FIG. 9, a portion of the silicon oxide film IMF located in a region where the columns are formed is removed by the photolithography process and the etching process on the silicon oxide film IMF, thereby exposing the surface of the epitaxial layer NEL.

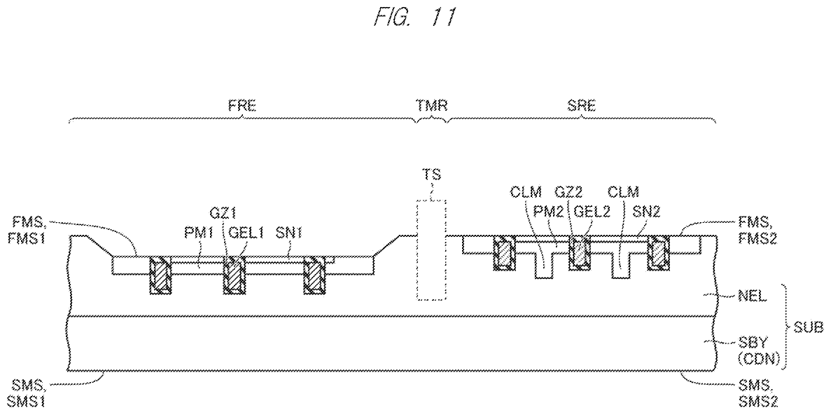

Next, the columns CLM are formed in the epitaxial layer NEL by injecting P-type impurities using the silicon oxide film IMF as an injection mask. Thereafter, the silicon oxide film IMF is removed. Next, as shown in FIG. 10, the gate electrode GEL1 is formed in the trench TRC1 in the first region FRE using a typical method with the gate oxide film GZ1 interposed therebetween. The gate electrode GEL2 is formed in the trench TRC2 in the second region SRE with the gate oxide film GZ2 interposed therebetween.

Next, a photoresist pattern (not shown) for forming a P⁻ region is formed by a predetermined photolithography process. Next, P-type impurities are injected using the photoresist pattern as an injection mask. This allows the P⁻ region PM1 to be formed in the first region FRE as shown in FIG. 11. The P⁻ region PM1 is formed so as to extend from the first main surface's first portion FMS1 to a position shallower than the bottom of the gate electrode GEL′. The P⁻ region PM2 is formed in the second region SRE. The P⁻ region PM2 is formed so as to extend from the first main surface's second portion FMS2 to a position shallower than the bottom of the gate electrode GEL2. In addition, the P⁻ region PM2 is formed so as to connect to the columns CLM. Thereafter, the photoresist pattern is removed.

Next, a photoresist pattern (not shown) for forming an N⁺ region is formed by a predetermined photolithography process. Next, N-type impurities are injected using the photoresist pattern as an injection mask. This allows the N⁺ region SN1 to be formed in the first region FRE as shown in FIG. 11. The N⁺ region SN1 is formed so as to extend from the first main surface's first portion FMS1 to a position shallower than the bottom of the P⁻ region PM1. The N⁺ region SN2 is formed in the second region SRE. The N⁺ region SN2 is formed so as to extend from the first main surface's second portion FMS2 to a position shallower than the bottom of the P⁻ region PM2. Thereafter, the photoresist pattern is removed.

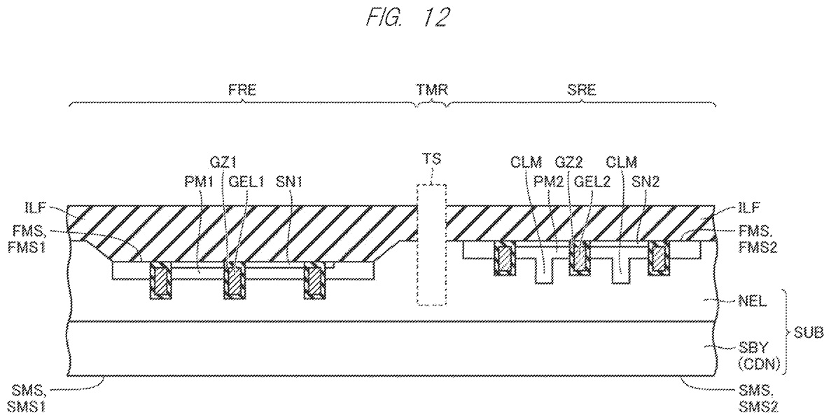

Next, as shown in FIG. 12, the interlayer insulating film ILF is formed so as to cover the first main surface FMS of the semiconductor substrate SUB. Next, a photoresist pattern (not shown) for forming contact openings is formed by a predetermined photolithography process. Next, the interlayer insulating film ILF is subjected to the etching process using the photoresist pattern as an etching mask.

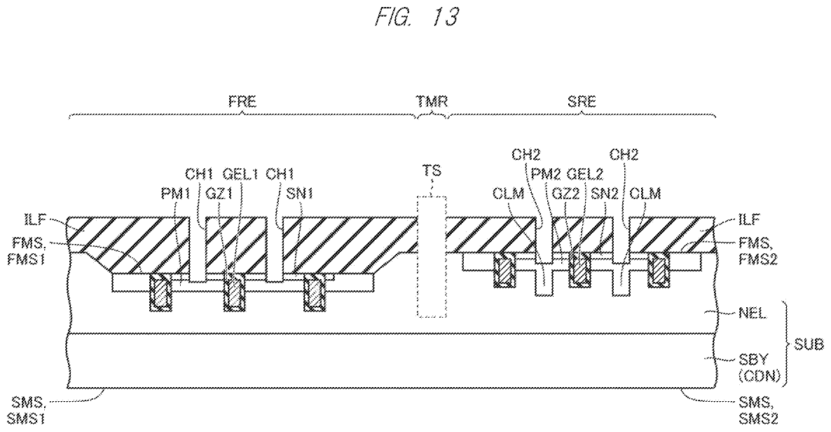

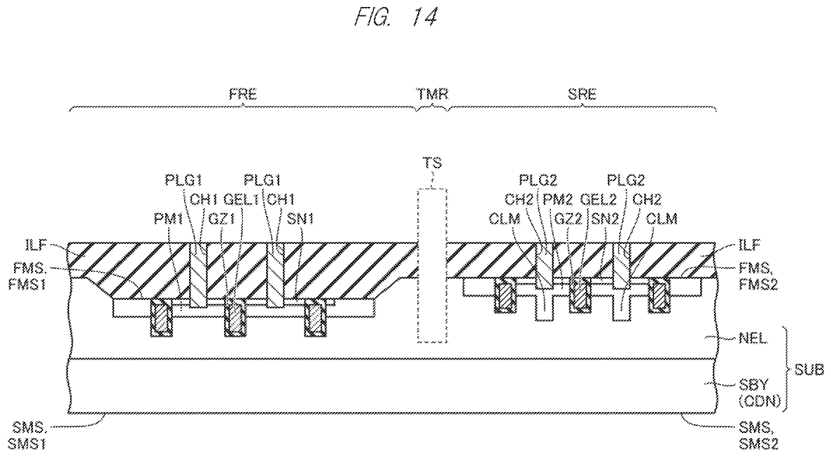

This allows contact openings CH1 to be formed in the first region FRE as shown in FIG. 13. The contact openings CH1 are formed so as to penetrate the interlayer insulating film ILF and the N⁺ region SN1, and reach the P⁻ region PM1. Contact openings CH2 are formed in the second region SRE. The contact openings CH2 are formed so as to penetrate the interlayer insulating film ILF and the N⁺ region SN2, and reach the P⁻ region PM2.

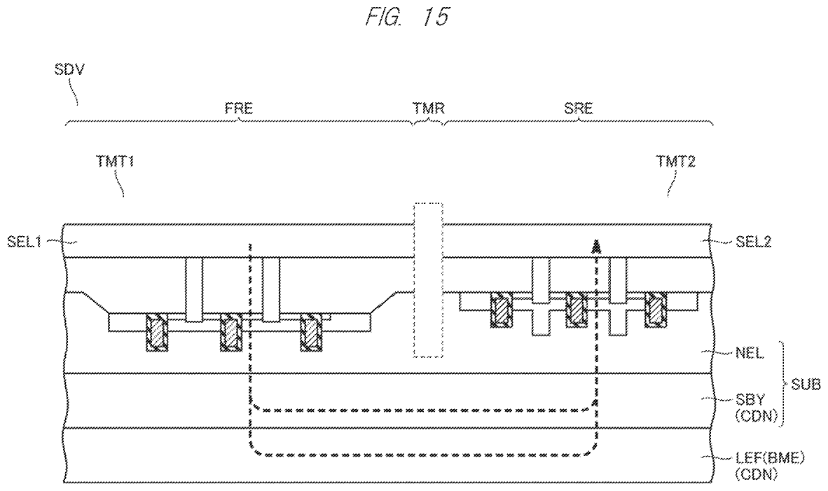

Next, a metal film made of aluminum or the like is formed by, for example, a sputtering method so as to fill the contact openings CH1 and the contact openings CH2. This allows the plugs PLG1 to be respectively formed in the contact openings CH1 in the first region FRE as shown in FIG. 14. The plugs PLG2 are respectively formed in the contact openings CH2 in the second region SRE.

Further, a metal film made of an aluminum film or the like is formed by a predetermined photolithography process and the etching process so as to cover the interlayer insulating film ILF. This allows the source electrode SEL1 and the gate G1 to be formed in the first region FRE (see FIG. 2). The source electrode SEL2 and the gate G2 are formed in the second region SRE (see FIG. 2).

Thereafter, the semiconductor substrate SUB on which the first power MOSFET TMT1 and the second power MOSFET TMT2 are formed is removed as a single chip by dicing the semiconductor substrate SUB. The semiconductor substrate SUB removed as a chip is completed as the semiconductor device SDV as shown in FIG. 3 and the like after undergoing steps such as mounting on the lead frame LEF.

Next, an operation of the above-described semiconductor device SDV will be described. First, a case where the battery BA is properly connected as shown in FIG. 1 will be described. In this case, voltages greater than or equal to a threshold value are respectively applied to the gate electrode GEL1 of the first power MOSFET TMT1 and the gate electrode GEL2 of the second power MOSFET TMT2, thereby turning on the first power MOSFET TMT1 and the second power MOSFET TMT2.

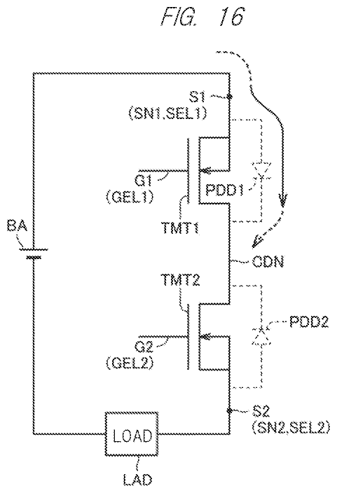

This allows current to flow from the battery BA into the second power MOSFET TMT2 via the first power MOSFET TMT1 as shown in FIGS. 1 and 15, thereby supplying power to the load LAD.

Next, the gate electrode GEL2 is electrically shorted to the source S2, thereby turning off the second power MOSFET TMT2. Here, as shown in FIG. 16, regardless of the state (on or off) of the first power MOSFET TMT1, current flows in a parasitic diode PDD1, thereby increasing a potential of the common drain region CDN. At this time, the breakdown voltage is maintained by the second power MOSFET TMT2 having a breakdown voltage of several times the voltage of the battery BA, thereby preventing current from flowing in the circuit.

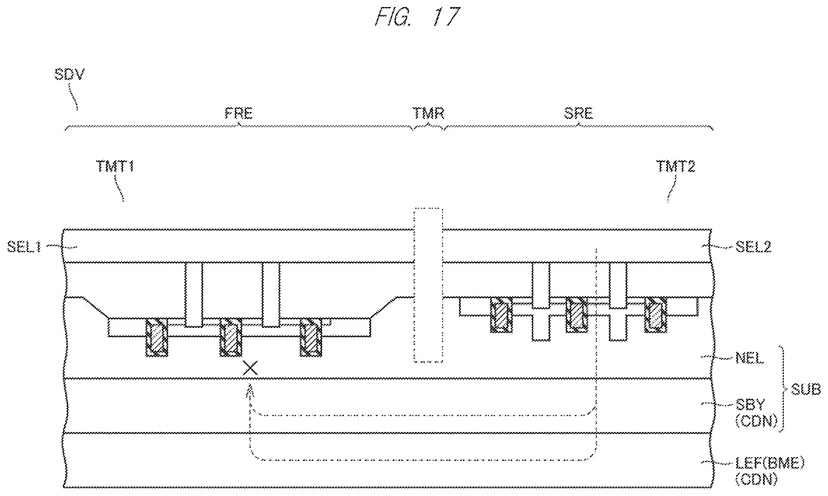

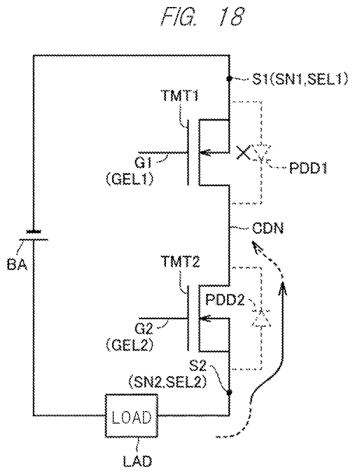

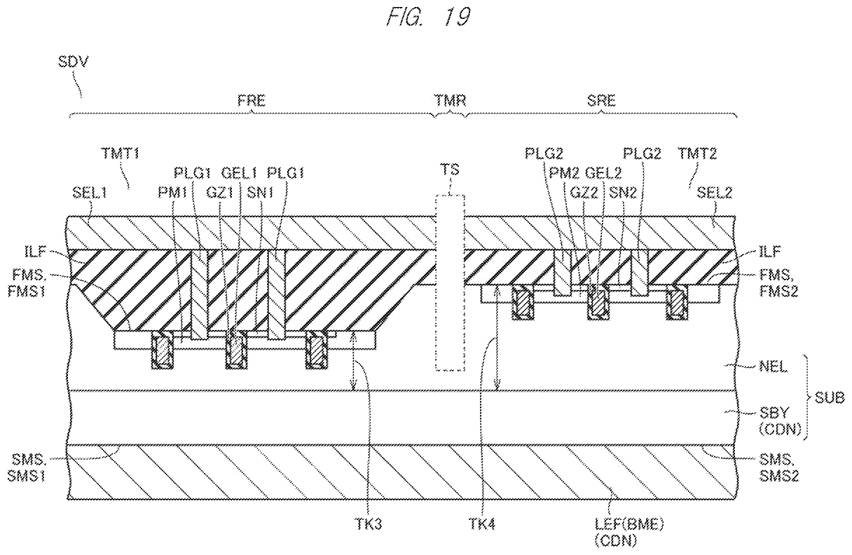

Next, a case where the battery BA is connected in reverse will be described. In this case, the first power MOSFET TMT1 is turned off. Here, as shown in FIGS. 17 and 18, regardless of the state (on or off) of the second power MOSFET TMT2, current flows in a parasitic diode PDD2, thereby increasing the potential of the common drain region CDN. At this time, the breakdown voltage is maintained by the first power MOSFET TMT1 having a breakdown voltage slightly higher than the voltage of the battery BA, thereby preventing current from flowing back into the circuit.

In this manner, the above-described semiconductor device SDV can prevent current from flowing in the circuit in both cases where the battery BA is properly connected to the semiconductor device SDV and where the battery BA is connected in reverse to the semiconductor device SDV (see FIG. 1).

Further, the above-described semiconductor device SDV can reduce the ON-resistance. This will be described hereinafter.

First, in the semiconductor device SDV, the breakdown voltage of the first power MOSFET TMT1 may be about a maximum rating of the voltage of the battery BA. On the other hand, the breakdown voltage of the second power MOSFET TMT2 needs to be, for example, several times the voltage of the battery BA, as it is necessary to take into account a surge and the like at the time of normal operation.

In order to ensure the breakdown voltage of this second power MOSFET TMT2, the thickness of the epitaxial layer NEL is increased. Increasing the thickness of the epitaxial layer NEL causes an excessive increase in the breakdown voltage of the first power MOSFET TMT1.

For this reason, in the normal operation, an increase in the thickness of the epitaxial layer NEL in the first power MOSFET TMT1 causes an increase in the ON-resistance, which may worsen characteristics for the semiconductor device SDV.

In the above-described semiconductor device SDV, the first main surface's first portion FMS1 in the first region FRE is located closer to the second main surface SMS than the first main surface's second portion FMS2 in the second region SRE. That is, a structure in which the thickness TK1 of the epitaxial layer NEL in the first region FRE is less than the thickness TK2 of the epitaxial layer NEL in the second region SRE is selectively formed.

This allows the ON-resistance to be reduced to the extent that the thickness TK1 of the epitaxial layer NEL in the first region FRE is selectively thinned while the thickness TK2 of the epitaxial layer NEL is set to an optimal thickness to ensure the breakdown voltage of the second power MOSFET TMT2. This means that the ON-resistance of the semiconductor device SDV can be easily optimized by selectively adjusting (thinning) the thickness TK1 of the epitaxial layer NEL in the first region FRE while ensuring the breakdown voltage of the second power MOSFET TMT2 (thickness TK2 of the epitaxial layer NEL).

The inventors of the present invention estimated a reduction effect of the ON-resistance. The effect on a resistance value per unit area of the first power MOSFET TMT1 with respect to the thickness (unit thickness) of the epitaxial layer NEL was approximately 1.2 mΩmm²/1.0 μm. Here, if an area of the first region FRE is assumed to be a few mm² and an area of the second region SRE is assumed to be 10 mm² or more, it was estimated that the ON-resistance can be reduced by 0.2 mΩ per 1.0 μm of the thickness of the epitaxial layer NEL. The reduction effect was found to be approximately 10% to 20% of the target ON-resistance.

### Second Embodiment

In the above-described semiconductor device, the second power MOSFET TMT2 having an SJ structure with the columns CLM is given as an example of the second power MOSFET TMT2. Hereinafter, a semiconductor device including the second power MOSFET TMT2 with no columns will be described as a second example of the semiconductor device SDV in which two power MOSFETs are connected in reverse and connected in series (connected in anti-series) to each other.

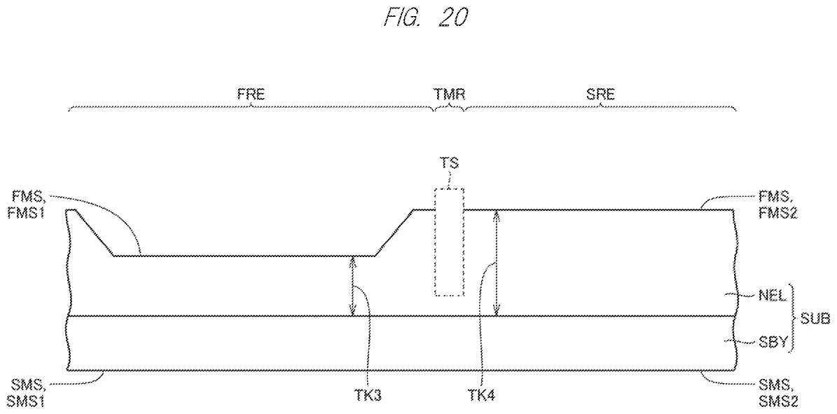

As shown in FIG. 19, the first power MOSFET TMT1 has a columnless structure with no columns, and the second power MOSFET TMT2 also has a columnless structure with no columns. In order to ensure that the second power MOSFET TMT2 having the columnless structure has the same breakdown voltage as in the second power MOSFET TMT2 having the column structure, it is necessary to increase the thickness TK4 of the portion of the epitaxial layer NEL that becomes the channel region where current conduction is performed.

For this reason, the thickness TK4 of the epitaxial layer NEL in the second region SRE in which the second power MOSFET TMT2 is formed is set to be thicker than the thickness TK2 of the epitaxial layer NEL in the second region SRE shown in FIG. 3.

However, an increase in the thickness of the epitaxial layer NEL in the second region SRE causes an increase in the thickness of the epitaxial layer NEL in the first region FRE in which the first power MOSFET TMT1 is formed, thereby causing an increase in the ON-resistance. Therefore, it is necessary to increase the thickness of the epitaxial layer NEL in the second region SRE to ensure the desired breakdown voltage, while it is also necessary to reduce the thickness of the portion of the epitaxial layer NEL in the first region FRE that becomes the channel region where current conduction is performed to achieve the desired ON-resistance.

For this reason, a difference (step) between the thickness TK4 of the epitaxial layer NEL in the second region SRE and a thickness TK3 of the epitaxial layer NEL in the first region FRE is greater than a difference (step) between the thickness TK2 and the thickness TK1 shown in FIG. 3. Note that the configuration other than this is similar to the configuration of the semiconductor device SDV shown in FIG. 3 and the like, and therefore, the same members are denoted by the same reference signs, and descriptions thereof will not be repeated unless otherwise necessary.

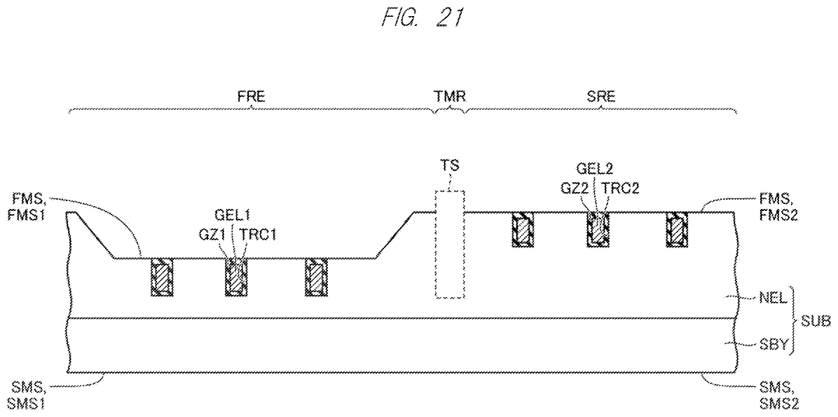

Next, an example of the method of manufacturing the above-described semiconductor device SDV will be described. First, for example, as in the steps shown in the above-described FIGS. 4 and 5, the position of the first main surface's first portion FMS1 is set back toward the substrate body SBY with respect to the position of the first main surface's second portion FMS2 as shown in FIG. 20 by the etching process on the epitaxial layer NEL.

At this time, an increase in the thickness TK4 of the epitaxial layer NEL in which the desired breakdown voltage is ensured causes the etching amount of the epitaxial layer NEL in the first region FRE to increase until it reaches the thickness TK3 of the epitaxial layer NEL that can achieve the desired ON-resistance. For this reason, the difference (step) between the position (height) of the first main surface's first portion FMS1 and the position (height) of the first main surface's second portion FMS2 is greater than the step difference achieved in the step shown in FIG. 5.

Next, the trench TRC1 is formed in the first region FRE and the trench TRC2 is formed in the second region SRE by the photolithography process and the etching process on the epitaxial layer NEL (see FIG. 21). Here, the difference (step) between the position (height) of the first main surface's first portion FMS1 and the position (height) of the first main surface's second portion FMS2 is large. For this reason, the photolithography process and the like may be performed twice to avoid defocusing.

Next, as shown in FIG. 21, the gate electrode GEL1 is formed in the trench TRC1 in the first region FRE using a typical method with the gate oxide film GZ1 interposed therebetween. The gate electrode GEL2 is formed in the trench TRC2 in the second region SRE with the gate oxide film GZ2 interposed therebetween.

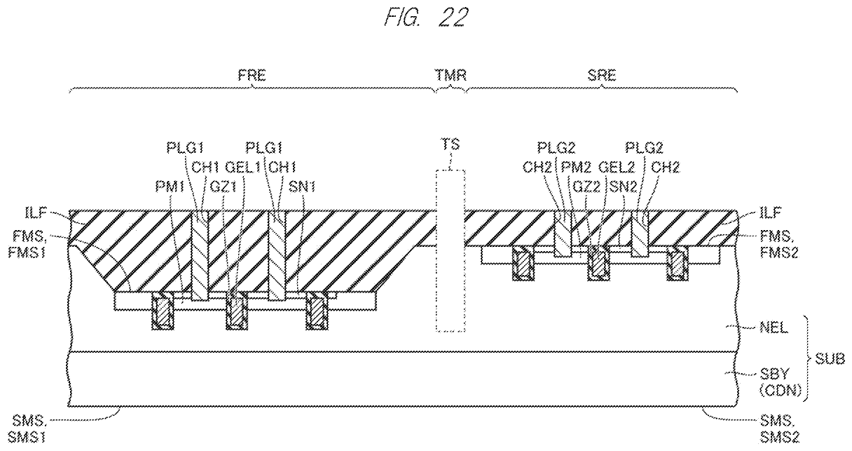

Next, after performing steps similar to those shown in FIGS. 11 to 14, the plugs PLG1 are respectively formed in the contact openings CH1 in the first region FRE as shown in FIG. 22. The plugs PLG2 are respectively formed in the contact openings CH2 in the second region SRE. Thereafter, after performing the steps of forming the source electrodes SEL1, SEL2 and the like, dicing the semiconductor substrate SUB and mounting it on the lead frame LEF, the semiconductor device SDV is completed as shown in FIG. 19.

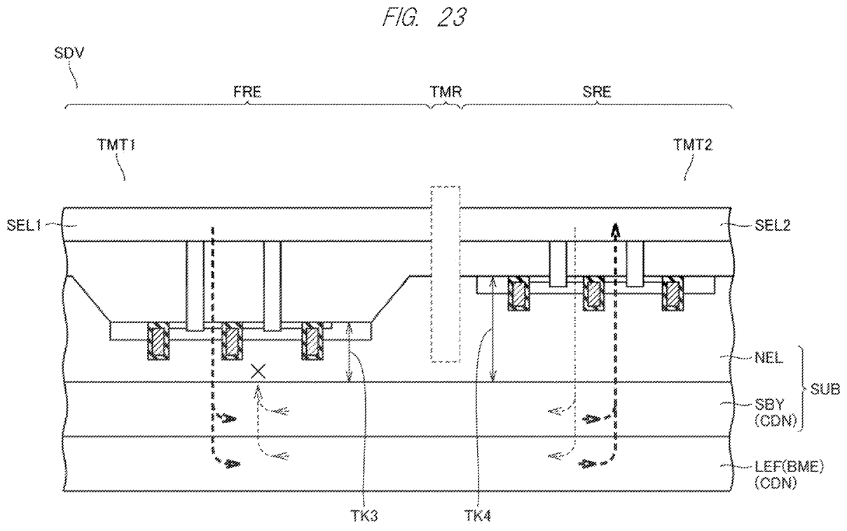

Next, an operation of the above-described semiconductor device SDV will be described. As in the above-described semiconductor device SDV, first, when turned on in a case where the battery BA is properly connected (see FIG. 1), current flows in the second power MOSFET TMT2 via the first power MOSFET TMT1 as shown in FIG. 23 (see thick broken arrow). At this time, the ON-resistance is reduced by the thickness TK3 of the epitaxial layer NEL (first power MOSFET TMT1) in the first region FRE being selectively set to be thin.

On the other hand, when turned off, the breakdown voltage is ensured by the epitaxial layer NEL (second power MOSFET TMT2) having the thickness TK4 set so as to have a breakdown voltage of several times the voltage of the battery BA.

Next, in a case where the battery BA is connected in reverse (see FIG. 1), the breakdown voltage is maintained by the first power MOSFET TMT1 having a breakdown voltage slightly higher than the voltage of the battery BA.

The above-described semiconductor device SDV has no columns. Omitting the step of forming the columns contributes to reducing the manufacturing cost. In addition, having no columns makes it possible to increase the thickness TK4 of the epitaxial layer NEL, thereby ensuring the breakdown voltage of the second power MOSFET TMT2.

Further, an increase in the thickness TK4 causes an the etching amount of the epitaxial layer NEL in the first region FRE to increase until it reaches the thickness TK3, whereby the effect on the ON-resistance caused by the increase in the thickness of the epitaxial layer NEL is minimized and the desired ON-resistance can be achieved. Further, the ON-resistance of the semiconductor device SDV can be easily optimized by selectively adjusting (thinning) the thickness TK3 of the epitaxial layer NEL in the first region FRE.

### Third Embodiment

Here, the semiconductor device SDV in which the substrate body is processed will be described as a third example of the semiconductor device SDV in which two power MOSFETs are connected in reverse and connected in series (connected in anti-series).

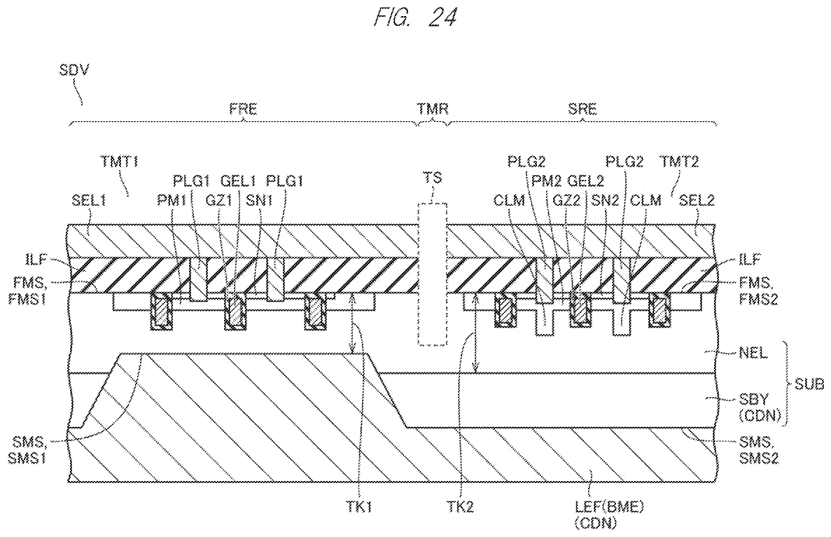

As shown in FIG. 24, the thickness TK1 of the portion of the epitaxial layer NEL in the first region FRE that becomes the channel region where current conduction is performed is less than the thickness TK2 of the portion of the epitaxial layer NEL in the second region SRE that becomes the channel region where current conduction is performed. The first main surface's first portion FMS1 and the first main surface's second portion FMS2 are located on the same plane. In a cross-sectional view, the second main surface's first portion SMS1 is located closer to the first main surface FMS than the second main surface's second portion SMS2.

The metal back surface BME or the like is formed so as to be in contact with the second main surface SMS including the second main surface's first portion SMS1. Note that the configuration other than this is similar to the configuration of the semiconductor device SDV shown in FIG. 3 and the like, and therefore, the same members are denoted by the same reference signs, and descriptions thereof will not be repeated unless otherwise necessary.

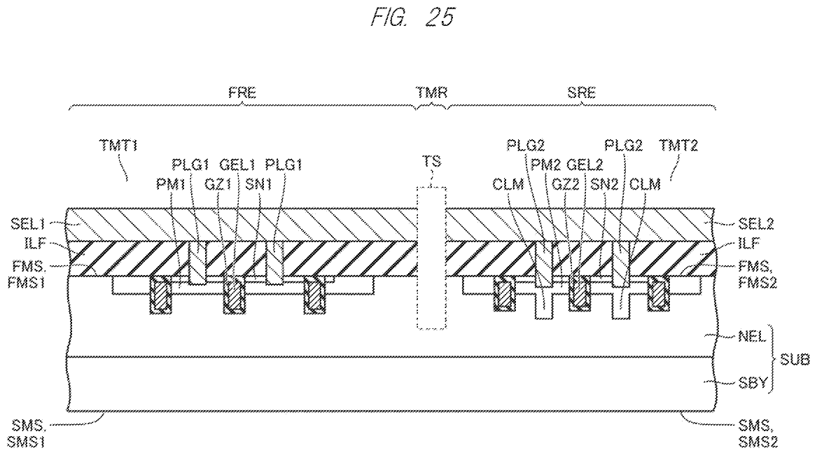

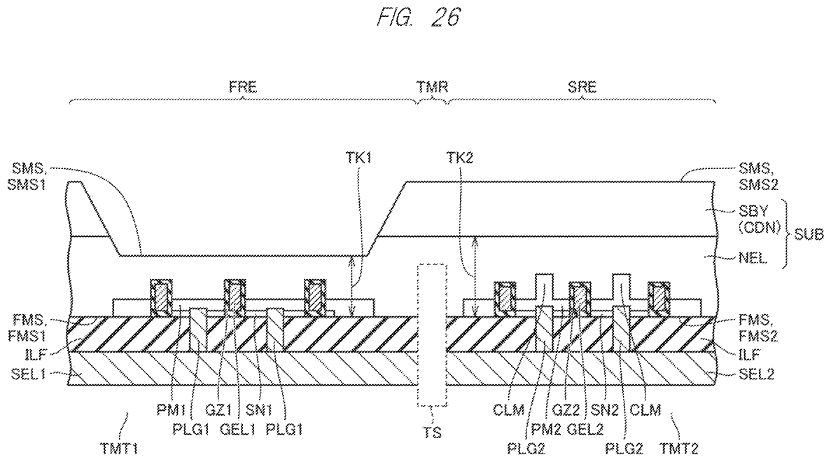

Next, an example of the method of manufacturing the above-described semiconductor device SDV will be described. First, the semiconductor substrate SUB is prepared, and the semiconductor substrate SUB is subjected to processes similar to the steps shown in FIGS. 8 to 14 without setting back the surface of the epitaxial layer NEL (first main surface's first portion FMS1) located in the first region FRE. Next, as shown in FIG. 25, the source electrode SEL1 is formed in the first region FRE, and the source electrode SEL2 is formed in the second region SRE.

Next, the substrate body SBY of the semiconductor substrate SUB is subjected to the etching process. As shown in FIG. 26, the substrate body SBY located in the first region FRE is subjected to, for example, the TMAH etching process. This allows etching to progress along the (111) plane orientation of the substrate body SBY, thereby exposing the epitaxial layer NEL. Further, etching progresses along the (111) plane orientation of the exposed epitaxial layer NEL such that the position of the second main surface's first portion SMS1 is set back toward the first main surface FMS with respect to the position of the second main surface's second portion SMS2.

Next, for example, the metal back surface BME is formed so as to be in contact with the second main surface SMS including the second main surface's first portion SMS1. Thereafter, after performing the step of dicing the semiconductor substrate SUB, the semiconductor device SDV is completed as shown in FIG. 24.

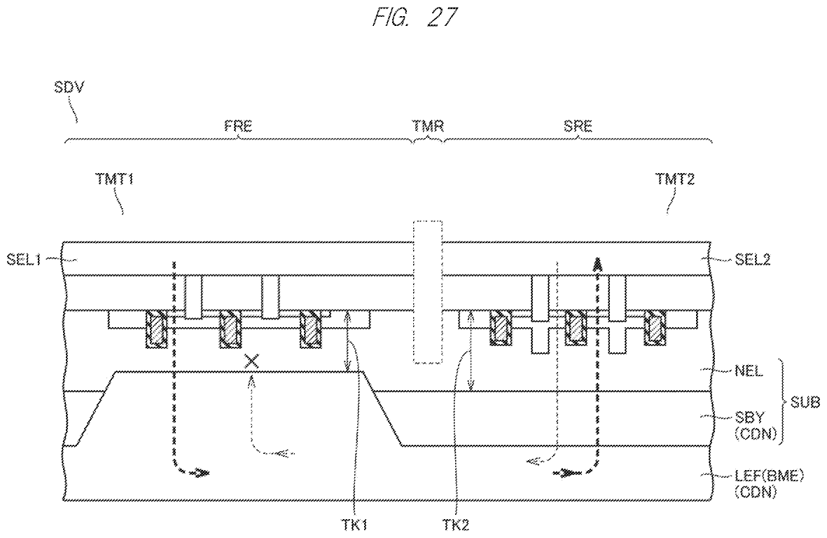

Next, an operation of the above-described semiconductor device SDV will be described. As in the semiconductor device SDV of the first embodiment, first, when turned on in a case where the battery BA is properly connected (see FIG. 1), current flows in the second power MOSFET TMT2 via the first power MOSFET TMT1 as shown in FIG. 27 (see thick broken arrow). At this time, the ON-resistance is reduced by the thickness TK1 of the epitaxial layer NEL (first power MOSFET TMT1) in the first region FRE being selectively set to be thin.

On the other hand, when turned off, the breakdown voltage is ensured by the epitaxial layer NEL (second power MOSFET TMT2) having the thickness TK2 set so as to have a breakdown voltage of several times the voltage of the battery BA.

Next, in a case where the battery BA is connected in reverse (see FIG. 1), the breakdown voltage is maintained by the first power MOSFET TMT1 having a breakdown voltage slightly higher than the voltage of the battery BA.

In the above-described semiconductor device SDV, the second main surface's first portion SMS1 in the first region FRE is located closer to the first main surface FMS than the second main surface's second portion SMS2 in the second region SRE. That is, a structure in which the thickness TK1 of the epitaxial layer NEL in the first region FRE is less than the thickness TK2 of the epitaxial layer NEL in the second region SRE is selectively formed.

This makes it possible to easily optimize the ON-resistance of the semiconductor device SDV by selectively adjusting (thinning) the thickness TK1 of the epitaxial layer NEL in the first region FRE while ensuring the breakdown voltage of the second power MOSFET TMT2 (thickness TK2 of the epitaxial layer NEL).

### Fourth Embodiment

Here, a first example of the semiconductor device SDV comprising one power MOSFET and one logic/analog transistor will be described.

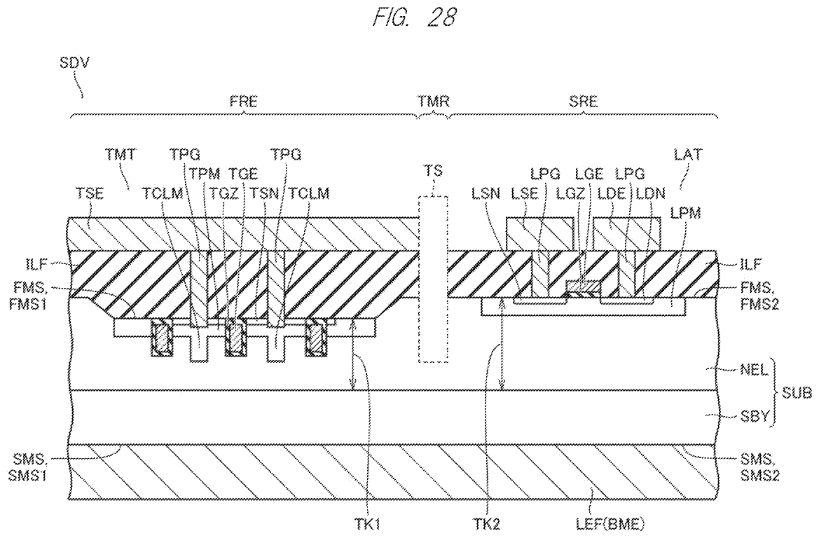

As shown in FIG. 28, a power MOSFET TMT and a logic/analog transistor LAT are formed on the same semiconductor substrate SUB. The power MOSFET TMT has the super-junction structure (SJ structure) with columns TCLM. The logic/analog transistor LAT is configured to control an operation (on and off) of the power MOSFET TMT.

The power MOSFET TMT is formed in the first region FRE. The logic/analog transistor LAT is formed in the second region SRE. The second main surface's first portion SMS1 and the second main surface's second portion SMS2 are located on the same plane. The first main surface's first portion FMS1 is located o closer to the second main surface SMS than the first main surface's second portion FMS2. The thickness TK1 of the portion of the epitaxial layer NEL in the first region FRE that becomes the channel region where current conduction is performed is less than the thickness TK2 of the portion of the epitaxial layer NEL in the second region SRE that becomes the channel region where current conduction is performed.

Next, structures of the power MOSFET TMT and the logic/analog transistor LAT will be described in more detail.

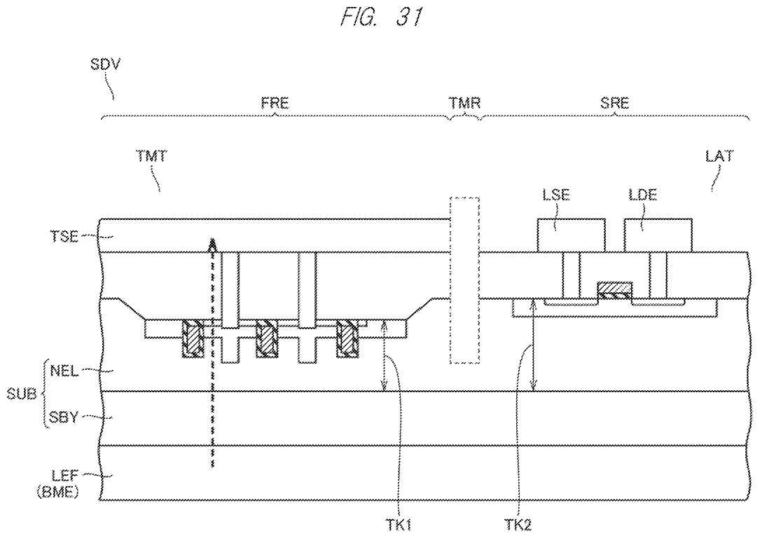

The first region FRE in which the power MOSFET TMT is formed has a trench TRC (see FIG. 30) in which a gate electrode TGE (first electrode) is formed with a gate oxide film TGZ (first insulating film) interposed therebetween. A P⁻ region TPM (first impurity region's first portion) is formed so as to extend from the surface of the first main surface's first portion FMS1 (epitaxial layer NEL) of the semiconductor substrate SUB to a position shallower than a bottom of the gate electrode TGE so as to be in contact with the gate oxide film TGZ.

An N⁺ region TSN (second impurity region's first portion) is formed so as to extend from the surface of the first main surface's first portion FMS1 (epitaxial layer NEL) of the semiconductor substrate SUB to a position shallower than a bottom of the P⁻ region TPM. The N⁺ region TSN serves as a source region of the power MOSFET TMT. P-type columns TCLM (second columnar bodies) are formed so as to extend from a bottom of a P⁻ region LPM2 toward the substrate body SBY.

A P⁻ region LPM (first impurity region's third portion) is formed in the second region SRE in which the logic/analog transistor LAT is formed so as to extend from the surface of the first main surface's second portion FMS2 (epitaxial layer NEL) to a predetermined depth. A source region LSN and a drain region LDN (pair of second impurity region's third portions) are formed in the P⁻ region LPM so as to extend from a surface (surface of the P⁻ region LPM) of the first main surface's first portion FMS1 (epitaxial layer NEL) to a position shallower than a bottom of the P⁻ region LPM. The source region LSN and the drain region LDN are formed so as to be spaced apart from each other. A gate electrode LGE (third electrode) is formed on the P⁻ region LPM and sandwiched between the source region LSN and the drain region LDN, with a gate oxide film LGZ (third insulating film) interposed therebetween.

The interlayer insulating film ILF is formed so as to cover the first main surface FMS of the semiconductor substrate SUB. Plugs TPG are formed in the first region FRE so as to penetrate the interlayer insulating film ILF. Plugs LPG are formed in the second region SRE so as to penetrate the interlayer insulating film ILF. A source electrode TSE is formed in the first region FRE so as to cover the interlayer insulating film ILF. A source electrode LSE and a drain electrode LDE are formed in the second region SRE so as to be in contact with the interlayer insulating film ILF.

The source electrode TSE and the N⁺ region TSN are electrically connected in the first region FRE via the plugs TPG. The source electrode LSE and the source region LSN are electrically connected in the second region SRE via the plugs LPG. The drain electrode LDE and the drain region LDN are electrically connected via the plugs LPG.

The semiconductor substrate SUB is mounted on the lead frame LEF. The lead frame LEF is arranged so as to be in contact with the second main surface SMS of the substrate body SBY (semiconductor substrate SUB). The metal back surface BME may be formed in addition to the lead frame LEF. Note that the configuration other than this is similar to the configuration of the semiconductor device SDV shown in FIG. 3 and the like, and therefore, the same members are denoted by the same reference signs, and descriptions thereof will not be repeated unless otherwise necessary.

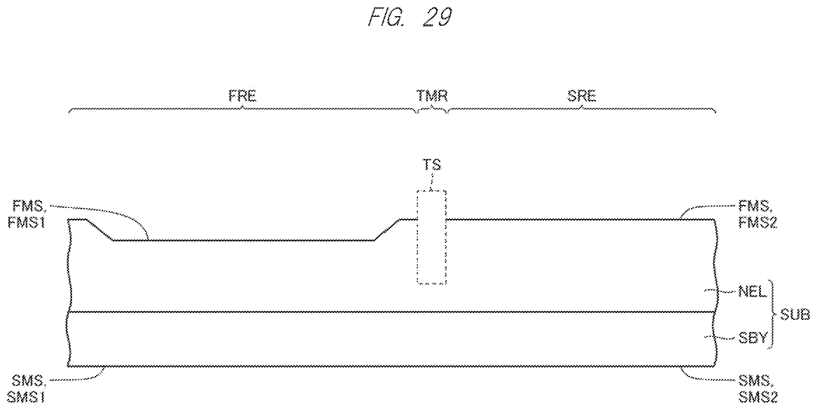

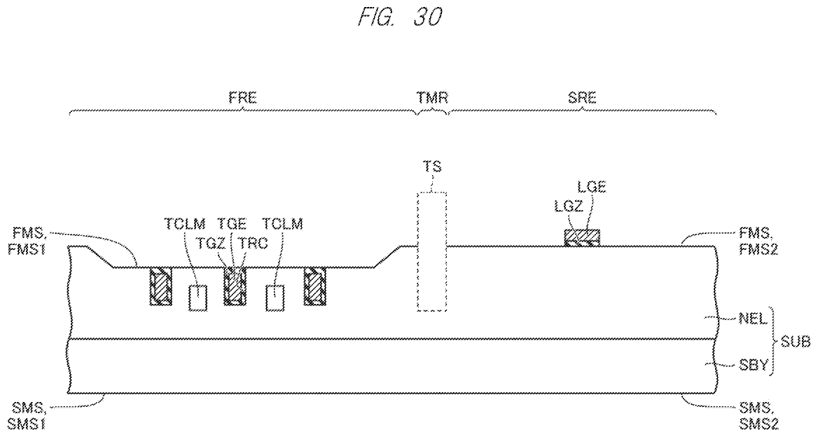

Next, an example of the method of manufacturing the above-described semiconductor device SDV will be described. First, for example, as in the steps shown in FIGS. 4 and 5, the position of the first main surface's first portion FMS1 is set back toward the substrate body SBY with respect to the position of the first main surface's second portion FMS2 as shown in FIG. 29 by the etching process on the epitaxial layer NEL.

Next, the trench TRC is formed in the first region FRE by the photolithography process and the etching process on the epitaxial layer NEL (see FIG. 30). Next, the columns TCLM are formed in the first region FRE as shown in FIG. 30 by a step similar to the step shown in FIG. 9. Next, the gate electrode TGE is formed in the trench TRC with the gate oxide film TGZ interposed therebetween. The gate electrode LGE is formed on the epitaxial layer NEL in the second region SRE with the gate oxide film LGZ interposed therebetween.

Here, the step of forming the gate oxide film TGZ and the step of forming the gate oxide film LGZ are separately performed such that the gate oxide film TGZ and the gate oxide film LGZ having thicknesses appropriate for performances of the power MOSFET TMT and the logic/analog transistor LAT can be formed.

Next, the semiconductor substrate SUB is subjected to processes similar to the steps shown in FIGS. 12 to 14. Next, the source electrode TSE is formed in the first region FRE, and the source electrode LSE and the drain electrode LDE are formed in the second region SRE (see FIG. 28). Thereafter, after performing the steps of dicing the semiconductor substrate SUB, mounting it on the lead frame LEF, and the like, the semiconductor device SDV is completed as shown in FIG. 28.

Next, an example of an operation of the above-described semiconductor device SDV will be described. On and off operations of the power MOSFET TMT formed in the first region FRE are controlled by the logic/analog transistor LAT formed in the second region SRE. As shown in FIG. 31, when the power MOSFET TMT is turned on, current flows from the lead frame LEF (metal back surface BME) toward the source electrode TSE (see broken arrow).

The above-described semiconductor device SDV can achieve the following effects. Usually, in the semiconductor device comprising the power MOSFET TMT and the logic/analog transistor LAT, the breakdown voltage of the logic/analog transistor LAT is designed to be higher than the breakdown voltage of the power MOSFET TMT.

In order to ensure the breakdown voltage of the logic/analog transistor LAT, it is necessary to set the thickness of the epitaxial layer NEL in the second region SRE to a desired thickness. On the other hand, setting the thickness of the epitaxial layer NEL in the first region FRE in which the power MOSFET TMT is formed to be the same as the thickness of the epitaxial layer NEL in the second region SRE would cause an increase in the ON-resistance when current flows in the power MOSFET TMT.

In the above-described semiconductor device SDV, the thickness TK1 of the epitaxial layer NEL in the first region FRE is less than the thickness TK2 of the epitaxial layer NEL in the second region SRE. This allows the ON-resistance to be reduced when current flows in the power MOSFET TMT.

In addition, the thickness TK1 of the epitaxial layer NEL in the first region FRE is less than the thickness TK2 of the epitaxial layer NEL in the second region SRE, whereby the breakdown voltage of the power MOSFET TMT becomes lower than the breakdown voltage of the logic/analog transistor LAT. This can prevent the power MOSFET TMT from breaking down first and the logic/analog transistor LAT from being destroyed by the breakdown, assuming a case where breakdown occurs in the semiconductor device SDV.

In this manner, in the above-described semiconductor device SDV, the breakdown voltage of the logic/analog transistor LAT can be ensured to prevent destruction by the breakdown from occurring, and the ON-resistance of the power MOSFET TMT can be reduced.

### Fifth Embodiment

Here, the semiconductor device SDV in which the substrate body is processed will be described as a second example of the semiconductor device SDV comprising one power MOSFET and one logic/analog transistor.

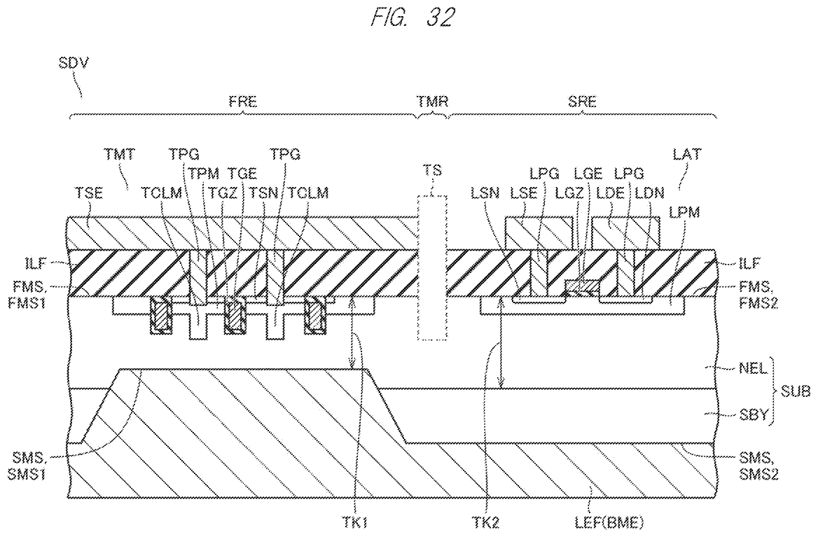

As shown in FIG. 32, the thickness TK1 of the portion of the epitaxial layer NEL in the first region FRE that becomes the channel region where current conduction is performed is less than the thickness TK2 of the portion of the epitaxial layer NEL in the second region SRE that becomes the channel region where current conduction is performed. The first main surface's first portion FMS1 and the first main surface's second portion FMS2 are located on the same plane. The second main surface's first portion SMS1 is located closer to the first main surface FMS than the second main surface's second portion SMS2.

The metal back surface BME or the like is formed so as to be in contact with the second main surface SMS including the second main surface's first portion SMS1. Note that the configuration other than this is similar to the configuration of the semiconductor device SDV shown in FIG. 28, and therefore, the same members are denoted by the same reference signs, and descriptions thereof will not be repeated unless otherwise necessary.

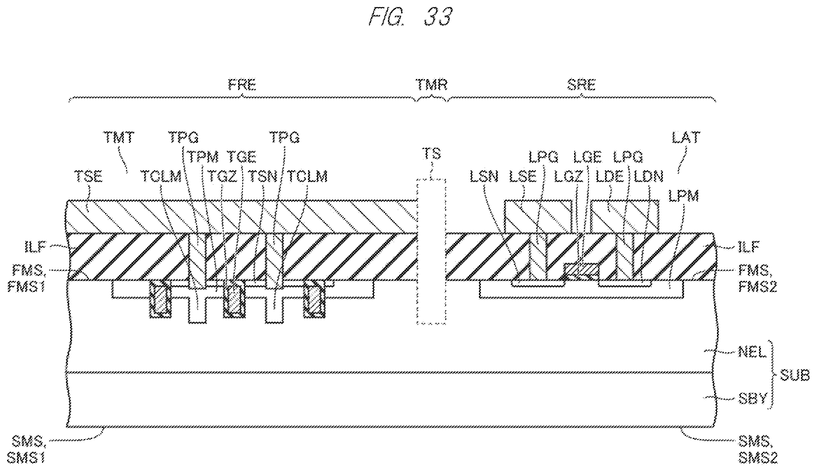

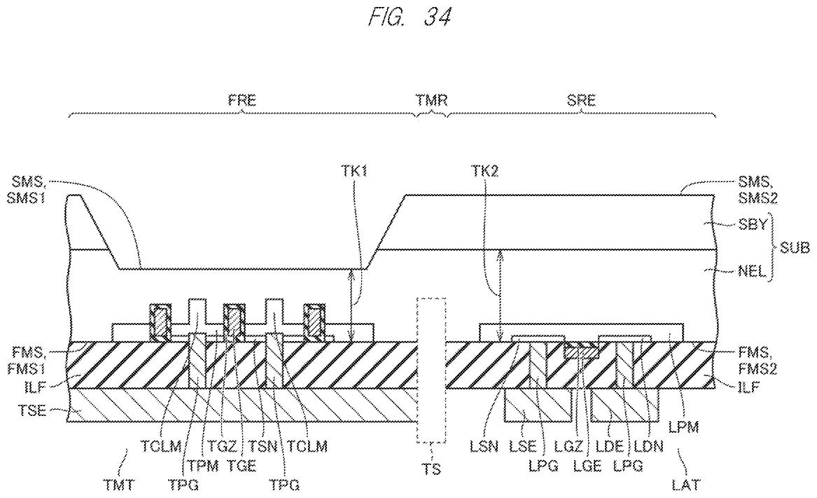

Next, an example of the method of manufacturing the above-described semiconductor device SDV will be described. First, the semiconductor substrate SUB is prepared, and the semiconductor substrate SUB is subjected to processes similar to the steps shown in FIGS. 30 to 31 without setting back the surface of the epitaxial layer NEL (first main surface's first portion FMS1) located in the first region FRE. This allows the source electrode TSE to be formed in the first region FRE as shown in FIG. 33. The source electrode LSE and the drain electrode LDE are formed in the second region SRE.

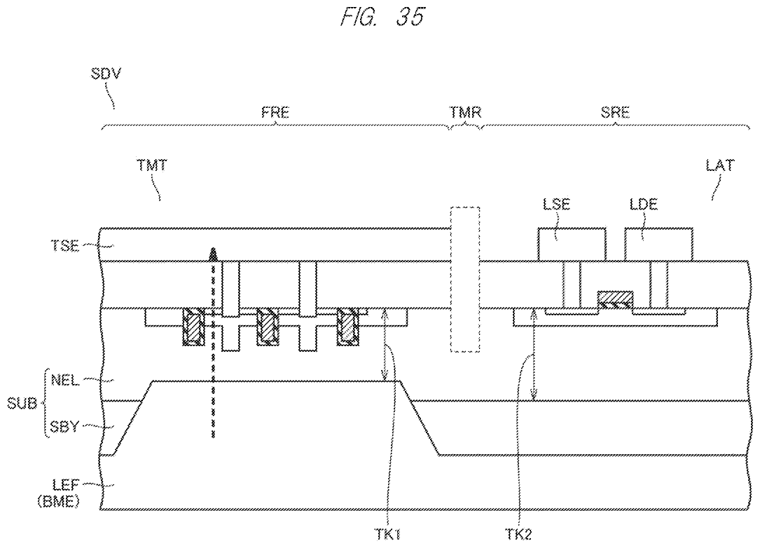

Next, the substrate body SBY of the semiconductor substrate SUB is subjected to the etching process. As shown in FIG. 34, the substrate body SBY located in the first region FRE is subjected to, for example, the TMAH etching process. This allows etching to progress along the (111) plane orientation of the substrate body SBY, thereby exposing the epitaxial layer NEL. Further, etching progresses along the (111) plane orientation of the exposed epitaxial layer NEL such that the position of the second main surface's first portion SMS1 is set back toward the first main surface FMS with respect to the position of the second main surface's second portion SMS2.

Next, for example, the metal back surface BME is formed so as to be in contact with the second main surface SMS including the second main surface's first portion SMS1. Thereafter, after performing the step of dicing the semiconductor substrate SUB, the semiconductor device SDV is completed as shown in FIG. 32.

Next, an example of an operation of the above-described semiconductor device SDV will be described. On and off operations of the power MOSFET TMT formed in the first region FRE are controlled by the logic/analog transistor LAT formed in the second region SRE. As shown in FIG. 35, when the power MOSFET TMT is turned on, current flows from the lead frame LEF (metal back surface BME) toward the source electrode TSE (see broken arrow).

As in the semiconductor device SDV described further above, in the above-described semiconductor device SDV, the thickness TK1 of the epitaxial layer NEL in the first region FRE is less than the thickness TK2 of the epitaxial layer NEL in the second region SRE. This allows the ON-resistance to be reduced when current flows in the power MOSFET TMT.

In addition, the thickness TK1 of the epitaxial layer NEL in the first region FRE is less than the thickness TK2 of the epitaxial layer NEL in the second region SRE, whereby the breakdown voltage of the power MOSFET TMT becomes lower than the breakdown voltage of the logic/analog transistor LAT. This can prevent the power MOSFET TMT from breaking down first and the logic/analog transistor LAT from being destroyed by the breakdown, assuming a case where breakdown occurs in the semiconductor device SDV.

In this manner, in the above-described semiconductor device SDV, the breakdown voltage of the logic/analog transistor LAT can be ensured to prevent destruction by the breakdown from occurring, and the ON-resistance of the power MOSFET TMT can be reduced.

In the above-described semiconductor device SDV, the power MOSFET TMT having the SJ structure is given as an example. Note that the semiconductor devices SDV described for the first to third embodiments may also use the first power MOSFET TMT1 having the SJ structure with columns as necessary. The semiconductor device described for each embodiment can be combined in various ways as necessary.

In the foregoing, the invention made by the present inventors has been concretely described based on the embodiments. However, it is needless to say that the present invention is not limited to the foregoing embodiments, and various modifications and alterations can be made within the scope of the present invention.

What is claimed is:

1. A semiconductor device comprising:
a semiconductor substrate having a first main surface and a second main surface opposite to each other;
a first region and a second region each defined in the semiconductor substrate;
a first switching element formed in the first region and configured to perform current conduction between the first main surface and the second main surface; and
a semiconductor element formed in the second region,
wherein the semiconductor substrate includes:
a substrate body of a first conductivity type; and
a semiconductor layer of the first conductivity type, the semiconductor layer being formed so as to be in contact with the substrate body, and the semiconductor layer having the first main surface,
wherein, in the semiconductor layer, a thickness of a portion located in the first region and where the current conduction by the first switching element is performed is a first thickness,
wherein, in the semiconductor layer, a thickness of a portion located in the second region and where current conduction by the semiconductor element is performed is a second thickness, and
wherein the first thickness is less than the second thickness.

2. The semiconductor device according to claim 1,
wherein the first main surface of the semiconductor substrate includes:
a first main surface's first portion located in the first region; and
a first main surface's second portion located in the second region,
wherein the first main surface's first portion is located closer to the second main surface than the first main surface's second portion.

3. The semiconductor device according to claim 1,
wherein the second main surface of the semiconductor substrate includes:
a second main surface's first portion located in the first region; and
a second main surface's second portion located in the second region, and
wherein the second main surface's first portion is located closer to the first main surface than the second main surface's second portion.

4. The semiconductor device according to claim 1,
wherein the first switching element includes:
a first electrode formed in a first trench formed in the semiconductor layer with a first insulating film interposed therebetween;
a first impurity region's first portion of a second conductivity type formed in the semiconductor layer so as to be in contact with the first insulating film and extend from the first main surface to a position shallower than a bottom of the first electrode; and
a second impurity region's first portion of the first conductivity type formed in the first impurity region's first portion so as to extend from the first main surface to a position shallower than a bottom of the first impurity region's first portion.

5. The semiconductor device according to claim 4,
wherein the first switching element includes a first columnar body of the second conductivity type extending from the first impurity region's first portion toward the substrate body.

6. The semiconductor device according to claim 1,
wherein the semiconductor element includes a second switching element connected in anti-series to the first switching element.

7. The semiconductor device according to claim 6,
wherein the second switching element includes:
a second electrode formed in a second trench formed in the semiconductor layer with a second insulating film interposed therebetween;
a first impurity region's second portion of the second conductivity type formed in the semiconductor layer so as to be in contact with the second insulating film and extend from the first main surface to a position shallower than a bottom of the second electrode; and
a second impurity region's second portion of the first conductivity type formed in the first impurity region's second portion so as to extend from the first main surface to a position shallower than a bottom of the first impurity region's second portion.

8. The semiconductor device according to claim 7,
wherein the second switching element includes a second columnar body of the second conductivity type extending from the first impurity region's second portion toward the substrate body.

9. The semiconductor device according to claim 1,
wherein the semiconductor element includes a control transistor configured to control an operation of the first switching element.

10. The semiconductor device according to claim 9,
wherein the semiconductor element includes:
a first impurity region's third portion of the second conductivity type formed in the semiconductor layer so as to extend from the first main surface toward the substrate body;
a pair of second impurity region's third portions of the first conductivity type, each formed in the first impurity region's third portion so as to be spaced apart from each other and extend from the first main surface to a position shallower than a bottom of the first impurity region's third portion; and
a third electrode formed on the first impurity region's third portion sandwiched by the pair of second impurity region's third portions, with a third insulating film interposed therebetween.

11. The semiconductor device according to claim 1,
wherein a lead frame is arranged on the second main surface of the semiconductor substrate.

12. The semiconductor device according to claim 1,
wherein the substrate body of the first conductivity type has a higher impurity concentration than the semiconductor layer of the first conductivity type.

13. A method of manufacturing a semiconductor device including steps of:
preparing a semiconductor substrate having a first main surface and a second main surface opposite to each other, wherein a first region and a second region are each defined in the semiconductor substrate, wherein the semiconductor substrate includes a substrate body of the first conductivity type and a semiconductor layer of the first conductivity type, wherein the substrate body has the second main surface, wherein the semiconductor layer is formed so as to be in contact with the substrate body, and wherein the semiconductor layer has the first main surface;
forming a first switching element in the first region of the semiconductor substrate, and forming a semiconductor element in the second region of the semiconductor substrate, the first switching element being configured to perform current conduction between the first main surface and the second main surface; and
making a first thickness less than a second thickness, the first thickness being a thickness of a portion in the semiconductor layer located in the first region and where the current conduction by the first switching element is performed, and the second thickness being a thickness of a portion in the semiconductor layer located in the second region and where current conduction by the semiconductor element is performed.

14. The method of manufacturing a semiconductor device according to claim 13,
wherein, in the step of preparing a semiconductor substrate,
a first main surface's first portion is defined in the first region of the first main surface, and
a first main surface's second portion is defined in the second region of the first main surface,
wherein, in the step of making the first thickness less than the second thickness, the first main surface's first portion is subjected to an etching process such that the first main surface's first portion is made to be closer to the second main surface than the first main surface's second portion.

15. The method of manufacturing a semiconductor device according to claim 13,
wherein, in the step of preparing a semiconductor substrate,
a second main surface's first portion is defined in the first region of the second main surface, and
a second main surface's second portion is defined in the second region of the second main surface,
wherein, in the step of making the first thickness less than the second thickness, the second main surface's first portion is subjected to an etching process such that the second main surface's first portion is made to be closer to the first main surface than the second main surface's second portion.

16. The method of manufacturing a semiconductor device according to claim 13,
wherein the step of forming a semiconductor element includes a step of forming a second switching element in the second region, the second switching element being connected in anti-series to the first switching element.

17. The method of manufacturing a semiconductor device according to claim 13,
wherein the step of forming a semiconductor element includes a step of forming a control transistor in the second region, the control transistor being configured to control an operation of the first switching element.
